(19) United States
(12) Patent Application Publication
(10) Pub. No.: US 2008/0186217 A1
(43) Pub. Date: Aug. 7, 2008

(54) LOW PIN COUNT HIGH SPEED INTERFACE FOR VIDEO AND AUDIO CODEC APPLICATIONS

(76) Inventors: Lei Chen, Santa Clara, CA (US); Dinesh Venkatachalam, Fremont, CA (US)

Correspondence Address: FRANK F. TIAN, 331-4A THIRD AVENUE, LONG BEACH, NJ, 07740, US

(21) Appl. No.: 11/672,036

(22) Filed: Feb. 6, 2007

(51) Int. Cl. H03M 3/04

(52) U.S. Cl. 341/143

(57) ABSTRACT

A receiver is provided that comprises at least one tuner. The tuner comprises a housing or packaging wall inclosing at least some elements of the tuner. The tuner further comprises at least one pin or lead leading outside or away from the housing, and a sigma-delta modulator receiving an analog input stream having at least one frequency from at least one tuner and output at least 1-bit data stream, with each 1-bit data stream associated with a physical communications line terminating on the lead or pin. The receiver has at least one digital filter digitally coupled to the sigma-delta modulator for filtering the at least 1-bit data stream.

### FIELD OF THE INVENTION

The present invention relates generally to communication devices. More specifically, the present invention relates to a low pin count high-speed interface for video and audio co-dec applications composition.

### BACKGROUND

The commonly known Sigma-Delta (ΣΔ) modulation is a kind of analog-to-digital signal or digital-to-analog conversion derived from delta modulation. In Sigma-Delta (ΣΔ) modulation, an analog to digital converter (ADC) or digital to analog converter (DAC) circuit is used. low-cost CMOS devices are typically used to realize the Sigma-Delta (ΣΔ) modulation.

U.S. Pat. No. 5,182,642 to Gersdorff, et al. discloses an apparatus and method for the compression and transmission of multiformat data in which video data is compressed, at a first site, by a transform scaling data compressor, and carrier signals are modulated with audio and digital data by a delta modulation data modulator and a delta-sigma modulation data modulator respectively. Their output signals are combined by a multichannel data compressor and transmitted to a second site, where the procedures are essentially reversed to effectively regenerate the data as originally formatted.

United States Patent Application No. 20070008202 to Giuseppe Li Puma discloses a sigma-delta converter that has a signal input for receiving a data word. A clock signal input is designed to supply a clock signal. The sigma-delta converter includes a first clocked-operation accumulator stage whose input side is connected to the signal input, and at least one second clocked-operation accumulator stage connected in series with the first accumulator stage, with its input side coupled to an accumulator output of the first accumulator stage. The sigma-delta converter is configured to process the data word upon each clock signal only in one accumulator stage in the first and the at least one second accumulator stage, and output the processed data word at the accumulator output of the one accumulator stage. As a result, a time-critical response during signal processing is limited just to the accumulator stage which is currently processing the data word.

Oversampling in an analog-to-digital converter is known. United States Patent Application No. 20070013566 to Shang-Yuan Chuang discloses a delta-sigma modulator that includes a chopper-stabilized integrator, a quantizer having an input coupled to an output of the integrator, an input signal acquiring circuit controlled by a switched reference feedback circuit and having an output coupled to the input of the integrator, and a frequency-shaped pseudo-random chopper clock signal generator circuit including a pseudo-random sequence generator and producing a frequency-shaped pseudo-random clock signal. Resetting circuitry is coupled to reset inputs of the pseudorandom sequence generator to reset it in synchronization with the digital output of the chopper-stabilized delta-sigma modulator to prevent noise caused by wrap-around operation of the pseudorandom sequence generator. A logic circuit produces chopper clock signals in response to the frequency-shaped pseudo-random clock signal and applies them to various input switches and output switches of the integrator.

Using a delta-sigma modulator in a reception system is known. United States Patent Application No. 20060193348 to Yukiko Unno et al. discloses a multiplexing device and multiplexed data transmission and reception system having a multiplexing device wherein a packet including a one-bit audio signal obtained by subjecting an analog audio signal to a delta sigma modulation process is multiplexed between a plurality of packets including a video signal having a variable bit rate by changing packet interval time information between the plurality of packets including the video signal having the variable bit rate.

As can be seen, due to the structural disposition of a sigma-delta modulator there is a need to incorporate part of the sigma-delta modulator within a tuner thereby clearly demarcating the analog realm and the digital realm.

### SUMMARY OF THE INVENTION

A low pin count high-speed interface for video and audio co-dec applications composition having clean specifications of analog and digital domains is provided.

A low pin count high-speed interface for video and audio co-dec applications composition having low pin-count is provided. Thereby eliminating or reducing unwanted noise in the system.

A low pin count high-speed interface for video and audio co-dec applications composition that is able to work with tuners at both baseband and intermediate frequency (IF) bands are provided.

A low pin count high-speed interface for video and audio co-dec applications composition having a flexible noise shaping function is provided.

A combined interface device disposed between an analog realm and a digital realm is provided. The interface comprises: a sigma-delta modulator receiving an analog input stream having at least one frequency from at least one tuner and output at least one 1-bit data stream, with each 1-bit data stream associated with a physical communications line; and at least one digital filter digitally coupled to the delta-sigma modulator for filtering the at least 1-bit data stream.

A tuner is provided that comprises: a housing or packaging wall inclosing at least some elements of the tuner; at least one pin or lead leading outside or away from the housing: and a sigma-delta modulator receiving an analog input stream having at least one frequency from at least one tuner and output at least 1-bit data stream, with each 1-bit data stream associated with a physical communications line terminating on the lead or pin.

A receiver is provided that comprises at least one tuner. The tuner comprises a housing or packaging wall inclosing at least some elements of the tuner. The tuner further comprises at least one pin or lead leading outside or away from the housing: and a sigma-delta modulator receiving an analog input stream having at least one frequency from at least one tuner and output at least 1-bit data stream, with each 1-bit data stream associated with a physical communications line terminating on the lead or pin. The receiver has at least one digital filter digitally coupled to the sigma-delta modulator for filtering the at least 1-bit data stream.

### BRIEF DESCRIPTION OF THE FIGURES

The accompanying figures, where like reference numerals refer to identical or functionally similar elements throughout the separate views and which together with the detailed description below are incorporated in and form part of the specification, serve to further illustrate various embodiments and to explain various principles and advantages all in accordance with the present invention.

FIG. 1 is an example of a receiver system in accordance with some embodiments of the invention.

FIG. 2 is an example of an interface of the present invention.

FIG. 3 is an example of a first order sigma-delta modulator.

FIG. 4 is a first graph of the present invention.

FIG. 5 is a second graph of the present invention.

FIG. 6 is an example of an alternative embodiment of the present invention.

FIG. 7 is an implementation of a receiver having a delta-sigma modulator.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION

Before describing in detail embodiments that are in accordance with the present invention, it should be observed that the embodiments reside primarily in combinations of method steps and apparatus components related to taking advantage of the structural disposition of a sigma-delta demodulator and incorporate part of the sigma-delta demodulator within a tuner. Accordingly, the apparatus components and method steps have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

In this document, relational terms such as first and second, top and bottom, and the like may be used solely to distinguish one entity or action from another entity or action without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “comprises . . . a” does not, without more constraints, preclude the existence of additional identical elements in the process, method, article, or apparatus that comprises the element.

It will be appreciated that embodiments of the invention described herein may be comprised of one or more conventional processors and unique stored program instructions that control the one or more processors to implement, in conjunction with certain non-processor circuits, some, most, or all of the functions of taking advantage of the structural disposition of a sigma-delta demodulator and incorporate part of the sigma-delta demodulator within a tuner described herein. The non-processor circuits may include, but are not limited to, a radio receiver, a radio transmitter, signal drivers, clock circuits, power source circuits, and user input devices. As such, these functions may be interpreted as steps of a method to perform taking advantage of the structural disposition of a sigma-delta demodulator and incorporate part of the sigma-delta demodulator within a tuner. Alternatively, some or all functions could be implemented by a state machine that has no stored program instructions, or in one or more application specific integrated circuits (ASICs), in which each function or some combinations of certain of the functions are implemented as custom logic. Of course, a combination of the two approaches could be used. Thus, methods and means for these functions have been described herein. Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation.

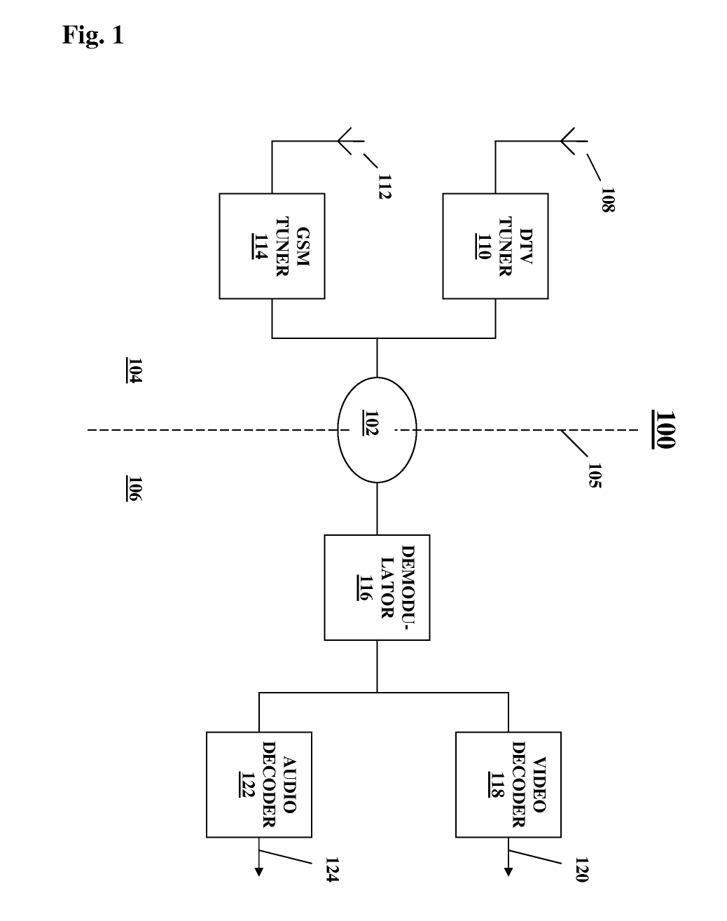

Referring to FIGS. 1-7, embodiments of the present invention are shown. Referring to specifically to FIG. 1, an example of a receiver system 100 in accordance with some embodiments of the invention is shown. An interface 102 having at least one analog input and at least one digital output is provided. Interface 102 defines or interfaces between an analog domain 104 and a digital domain 106. A line of division 105 physically divides the analog domain 104 and digital domain 106. Line of division 105 passes through or physically divides interface 102 as well. In analog domain 104, at least one tuner adapted to receive one type of wireless signals is provided. For example, a first antenna 108 may be provided to receive a digital television (DTV) signal, which is adapted to be processed by a DTV tuner 110. DTV tuner 110 operates in analog domain 104, and may serve as an input to interface 102. For yet another example, a second antenna 112 may be provided to receive a Global System for Mobile Communications (GSM) signal, which is adapted to be processed by a GSM tuner 114. GSM tuner 114 operates within analog domain 104, and may also serve as an input to interface 102. Other types of tuners (not shown) may operate in the analog domain 104 and serve as the predecessor to forming an input to interface 102. These tuners include WiMax, WiFi, CDMA types of tuners. On the digital domain 106 side, interface 102 is signally coupled to a demodulator 116. Demodulator 116 selectively demodulates or differentiates the digital symbols or information and subjects different types of digital information to their respective decoders. For example, a video decoder 118 receives the demodulated video information from demodulator 116 and outputs the decoded video information 120 for further processing in such devices as a TV receiver. For yet another example, an audio decoder 122 receives the demodulated audio information from demodulator 116 and outputs the decoded audio information 124 for further processing in such devices as a cellular phone.

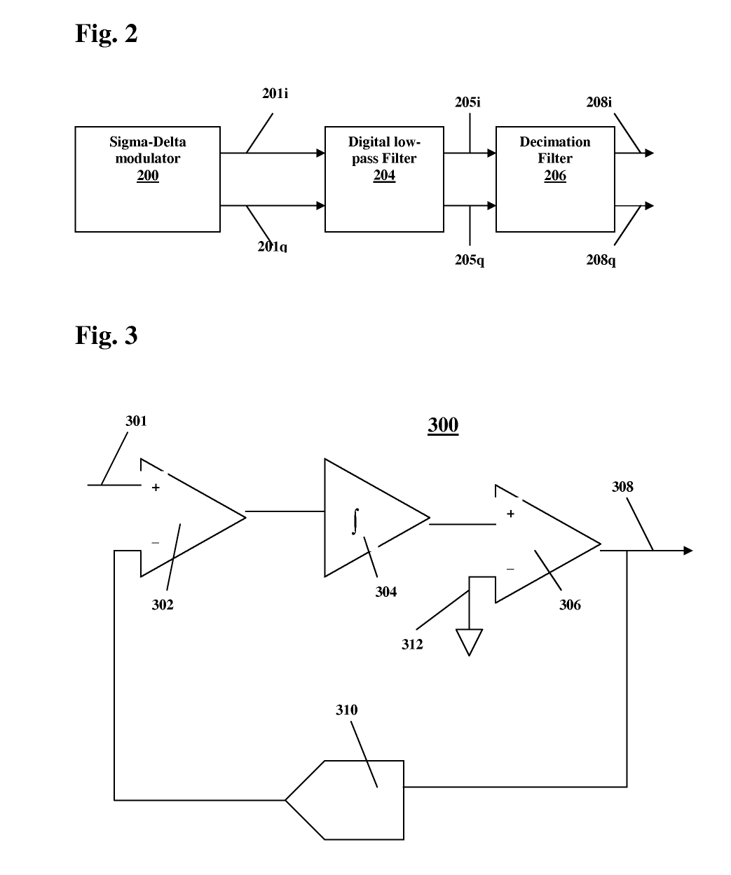

Referring specifically to FIG. 2, an example of an interface 102 of the present invention is shown. Interface 102 includes a sigma-delta modulator 200 which receives analog signals in analog domain 104. The analog signals may be audio/video signals, or the like. Also, the analog signals may be voice signal as well. For output, interface 102 has two physical lines or pins comprising two associated one-bit (1-bit) data streams with a first stream referred to as the in-phase (I) component 201i and a second stream referred to as quadrature (Q) component 201q. both 1-bit streams of in-phase (I) component 201i and quadrature (Q) component 201q are further subjected to filtering and then output for domodulations. The filters may include a digital low pass filter 204 which receive the 1-bit streams of in-phase (I) component 201i and quadrature (Q) component 201q and filters the 1-bit streams into multi-bits data 205 for further filtering by a decimation filter 206 with output 208 for demodulation.

Referring specifically to FIG. 3, an example of a first order sigma-delta modulator 300 is shown. The example depicts a first order sigma-delta modulator, but higher ordered sigma-delta modulators are contemplated as well in the present invention. An analog input signal 301 is adapted as the input for a difference amplifier 302 at the positive (“+”) input lead of difference amplifier 302. Signally coupled to difference amplifier 302 is an integrator 304. Integrator 304 is signally coupled to a comparator 306 with the output of integrator 304 serving as the input to comparator 306 at the positive (“+”) input lead of comparator 306. Comparator 306 functions as a one-bit analog to digital converter (ADC). After the ADC, the digital converted one-bit digital signal 308 is further subjected to filtering by such filters as 204 and 206. Converted one-bit digital signal 308 is further used as the feedback signal to difference amplifier 302 at the positive (“−”) input lead of difference amplifier 302 with a one-bit digital to analog converter (DAC) 310 interposed therebetween. Digital to analog converter (DAC) 310 functions to convert digital signals from digital domain 106 to analog signals of analog domain 104. As can be seen, line of division 105 is a clear demarcation line in this case.

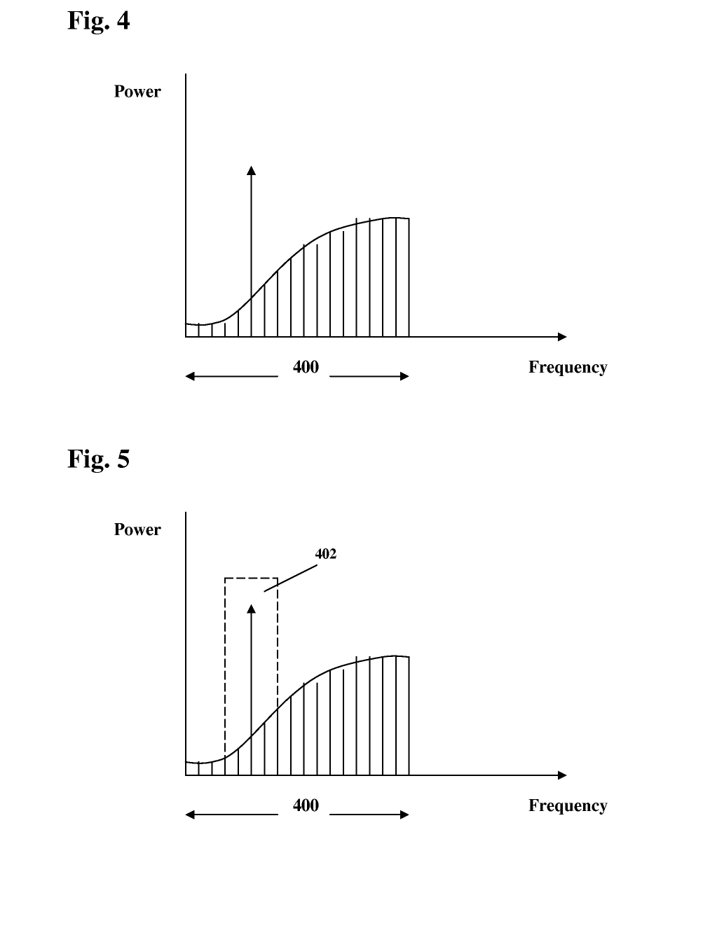

Referring specifically to FIGS. 4-5, a first and second graph of the present invention is depicted. The function of 300 is to make rough evaluations of analog input signal 301. An error can be measured and integrated by integrator 304 and then compensated for that error via a feedback loop as shown in FIG. 3. The mean output value is then equal to the mean input value if the integral of the error is finite. It is noted that the number of integrators, and consequently, the numbers of feedback loops, indicates the order of a ΣΔ-modulator; a first order ΣΔ modulator is shown in FIG. 3. First order modulators are very stable, but for higher ordered modulators stability must be taken further into account. 300 uses a combination of oversampling and noise shaping to achieve a higher dB signal improvement.

ΣΔ modulation is based on the technique of oversampling to reduce the noise in a band of interest 400. For merely oversampling, the quantization noise is the same both in a Nyquist converter area 402 and in an oversampling convertor area or in the band of interest 400. As can be seen, band of interest 400 is distributed over a larger spectrum. In 300, noise is further reduced at low frequencies, which is the band where the signal of interest is, and it is increased at the higher frequencies, where it can be filtered. This is commonly known as noise shaping.

Oversampling also achieves a speed/resolution tradeoff in that the decimation filter 206 not only filters the whole sampled signal in the band of interest 400 thereby cutting the noise at higher frequencies, but also reduces the frequency of 208 thereby increasing the resolution of same.

In other words, the density of “ones” at the modulator is proportional to the input signal. For an increasing input, the comprator 306 generates a increased number of “ones”, and vice versa for a decreasing input. By summing the error voltage, the integrator 304 acts as a lowpass filter to quantization noise. Therefore, most of the quantization noise is pushed into higher frequencies. As can be seen, oversamling not change the total noise power, but it change the distribution of the noise over a segment of frequency. Furthermore, a digital filter such as digital low pass filter 204 or decimation filter is applied in conjunction with sigma-delta modulator 200. The way, more noise is reduced as compared to merely oversampling. Based upon experiments, a 9 dB improvement in signal noise ratio (SNR) is achieved for first order in each doubling of sampling rate. For higher orders of quantization more than one stage of integration and summing occur. For example, a second order sigma-delta modulator provides a 15 dB improvement in SNR for every doubling of the sampling rate.

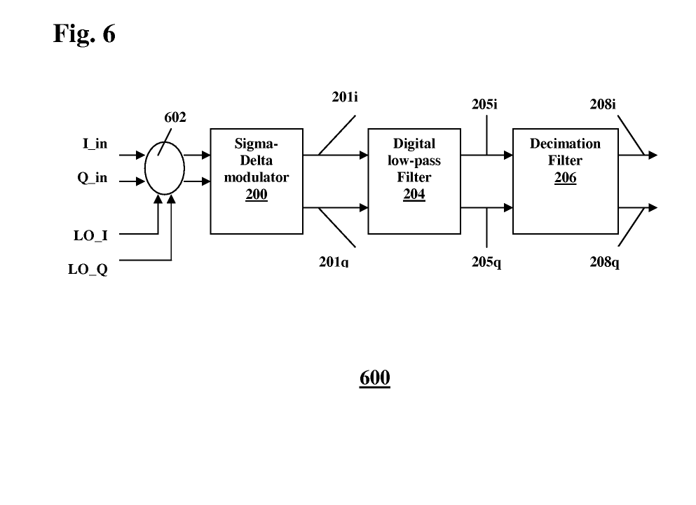

Referring specifically to FIG. 6 an example of an alternative embodiment 600 of the present invention is shown. The intermediate frequency (IF) and base band signals include I_in, LO_I and LO_Q, Q_in. For baseband, I_in and Q_in are used as inputs, for IF, I_in is used as input, Q_in is not used. LO_I and LO_Q are local oscillators, which are used to convert baseband or IF at different frequencies to the common lower valued IF. The intermediate frequency (IF) and base band signal are first subject to (input to) a mixer 602 to output a pair of derived frequency signals 604 that serves as the input to sigma-delta modulator 200. The remaining elements of FIG. 6 are structurally similar with that of FIG. 2 in that sigma-delta modulator 200 which receives analog signals in analog domain 104. For output, interface 102 has two physical lines or pins comprising two associated one-bit (1-bit) data streams with a first stream referred to as the in-phase (I) component 201i and a second stream referred to as quadrature (Q) component 201q. both 1-bit streams of in-phase (I) component 201i and quadrature (Q) component 201q are further subjected to filtering and then output for domodulations. The filters may include a digital low pass filter 204 which receive the 1-bit streams of in-phase (I) component 201i and quadrature (Q) component 201q and filters the 1-bit streams into multi-bits data 205 for further filtering by a decimation filter 206 with output 208 for demodulation.

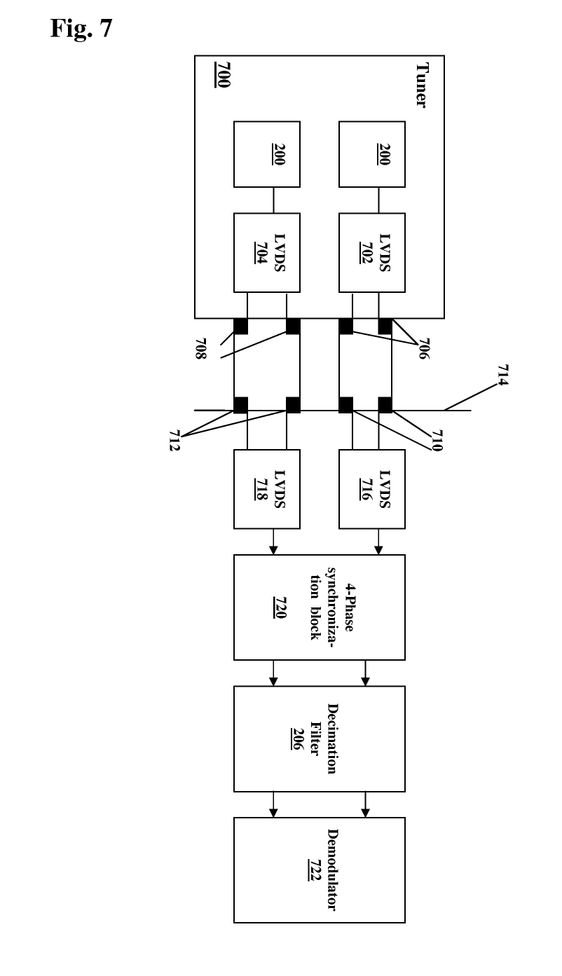

Referring specifically to FIG. 7 an implementation of a receiver having a delta-sigma modulator is depicted. A tuner 700 incorporating the sigma-delta modulator 200 is provided. Specifically, two sigma-delta modulators 200 is coupled to a specific low voltage differential signaling block (LVDS) wherein the I-signal or Q-signal are further subdivided into I₊-signal and L-signal, or Q₊-signal and Q₋-signal in this case LVDS 702 and LVDS 704 respectively. Tuner 700 comprises two sigma-delta modulator 200 with one for 1 and the other for Q signal paths respectively. Each path has leads or pins to physically connect with other components or devices. Each path comprises two signal lines terminating onto a pair of leads or pins. In the case of I signals, the two signal lines terminates onto pair of leads or pins 706. In the case of Q signals, the two signal lines terminate onto pair of leads or pins 708. As can be seen, due to the physical nature of sigma-delta modulator 200, a limited number of lines are required for the 1-bit digital data transfer or movement. In this example, only four physical lines or leads, or pins are needed. A set of corresponding leads, or pins 710 712 corresponding to leads or pins 708 and leads or pins 706 are formed on a coupling device having a physical boundary or surface 714. In turn, each I-signal and Q-signal is respectively subjected to LVDS 716 and LVDS 718. The outputs of 716 and 718 are input to a 4-phase synchronization block 720. The signals further flow into a 206, and than processed by a demodulator 722. The resultant signals, e.g. MPEG2 signals, after passing through a MPEG decoder can be further used by or coupled to, for example, a display device.

It is noted that the present invention contemplates using the PN sequence disclosed in U.S. Pat. No. 7,072,289 to Yang et al which is hereby incorporated herein by reference.

In the foregoing specification, specific embodiments of the present invention have been described. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

What is claimed is:

1. A combined interface device disposed between an analog realm and a digital realm, the interface comprising:
a sigma-delta modulator receiving an analog input stream having at least one frequency from at least one tuner and output at least one 1-bit data stream, with each 1-bit data stream associated with a physical communications line; and
at least one digital filter digitally coupled to the delta-sigma modulator for filtering the at least 1-bit data stream.

2. The combined interface device of claim 1, wherein the analog input stream is associated with a wireless signal received from at least one antenna.

3. The combined interface device of claim 1, wherein the analog input stream.

4. The combined interface device of claim 1, wherein the digital filter comprises a digital low pass filter.

5. The combined interface device of claim 1, wherein the digital filter comprises a decimation filter.

6. The combined interface device of claim 1, wherein the at least one frequency comprises a baseband frequency.

7. The combined interface device of claim 1, wherein the at least one frequency comprises an intermediate frequency (IF).

8. A tuner comprising:
a housing or packaging wall inclosing at least some elements of the tuner;
at least one pin or lead leading outside or away from the housing: and
a sigma-delta modulator receiving an analog input stream having at least one frequency from at least one tuner and output at least 1-bit data stream, with each 1-bit data stream associated with a physical communications line terminating on the lead or pin.

9. The tuner of claim 1, wherein the analog input stream.

10. The tuner of claim 1, wherein the at least one frequency comprises a baseband frequency.

11. The tuner of claim 1, wherein the at least one frequency comprises an intermediate frequency (IF).

12. The tuner of claim 1, wherein the analog input stream is associated with a wireless signal received from at least one antenna.

13. A receiver comprising:
at least one tuner, the tuner comprising,
a housing or packaging wall inclosing at least some elements of the tuner;
at least one pin or lead leading outside or away from the housing: and
a sigma-delta modulator receiving an analog input stream having at least one frequency from at least one tuner and output at least 1-bit data stream, with each 1-bit data stream associated with a physical communications line terminating on the lead or pin; and
at least one digital filter digitally coupled to the sigma-delta modulator for filtering the at least 1-bit data stream.

14. The receiver of claim 13, wherein the analog input stream is associated with a wireless signal received from at least one antenna.

15. The receiver of claim 13, wherein the analog input stream.

16. The receiver of claim 13, wherein the digital filter comprises a digital low pass filter.

17. The receiver of claim 13, wherein the digital filter comprises a decimation filter.

18. The receiver of claim 13, wherein the at least one frequency comprises a baseband frequency.

19. The receiver of claim 13, wherein the at least one frequency comprises an intermediate frequency (IF).

20. The receiver of claim 13, wherein the at least one tuner comprises a DTV tuner.

21. The receiver of claim 13, wherein the at least one tuner comprises a GSM tuner.

22. The receiver of claim 13, wherein the at least one tuner comprises a CDMA tuner.

23. The receiver of claim 13, wherein the at least one tuner comprises a WiMax tuner.
